(19) United States
(12) Patent Application Publication
(10) Pub. No.: US 2026/0334028 A1
(43) Pub. Date: Oct. 22, 2026

(54) DISPLAY APPARATUS INCLUDING DUMMY LINES AND ELECTRONIC DEVICE INCLUDING THE SAME

(71) Applicant: SAMSUNG DISPLAY CO., LTD., YONGIN-SI (KR)

(72) Inventors: Minji Kim, YONGIN-SI (KR); Younggu Kang, YONGIN-SI (KR); Wondo Kim, YONGIN-SI (KR); Hyeondo Park, YONGIN-SI (KR); Hyunsung Park, YONGIN-SI (KR)

(21) Appl. No.: 19/640,864

(22) Filed: Apr. 7, 2026

(30) Foreign Application Priority Data
Apr. 18, 2025 (KR) 10-2025-0050966

(51) Int. Cl. H10K 59/131; H10K 59/88

(52) U.S. Cl. CPC H10K 59/131; H10K 59/88

(57) ABSTRACT

A display apparatus includes a substrate including a display area and a peripheral area. A plurality of pixels is disposed in the display area and each includes at least one light-emitting diode and at least one pixel circuit. A plurality of signal lines is connected to the plurality of pixels and each of the signal lines extend in a first direction. A plurality of dummy lines is adjacent to the plurality of signal lines and is disposed within the peripheral area, separated from the plurality of pixels, and each of the dummy lines extends in the first direction. Ends of at least some dummy lines from among the plurality of dummy lines are spaced apart from one another in the first direction.

### CROSS-REFERENCE TO RELATED APPLICATION

This application claims priority under 35 U.S.C. §119 to Korean Patent Application No. 10-2025-0050966, filed on Apr. 18, 2025, in the Korean Intellectual Property Office, the disclosure of which is incorporated by reference herein in its entirety.

### TECHNICAL FIELD

The present disclosure relates to a display apparatus, and more particularly, to a display apparatus including dummy lines and an electronic device including the same.

### DISCUSSION OF THE RELATED ART

An electronic device may be used to present video or still images by using an integrated display apparatus. Such a display apparatus may generate the video and/or still images by emitting light from light-emitting diodes provided therein. Recently, display apparatuses have been applied to a wider variety of devices, and numerous structural improvements have been proposed to enhance their performance and image quality.

### SUMMARY

A display apparatus includes a substrate including a display area and a peripheral area. A plurality of pixels is disposed in the display area. Each of the plurality of pixels includes at least one light-emitting diode and at least one pixel circuit. A plurality of signal lines is electrically connected to the plurality of pixels. Each of the plurality of signal lines extends in a first direction. A plurality of dummy lines is disposed adjacent to the plurality of signal lines and within the peripheral area. The plurality of dummy lines is separated from the plurality of pixels. Each of the plurality of dummy lines extends in the first direction. Ends of at least some dummy lines from among the plurality of dummy lines are spaced apart from one another in the first direction.

The plurality of dummy lines may include a first dummy line and a second dummy line. The second dummy line may be disposed between the first dummy line and the display area, and an end of the first dummy line may extend farther in the first direction than does an end of the second dummy line.

A distance in the first direction between the end of the first dummy line and the end of the second dummy line may correspond to a length of one of the plurality of pixels in the first direction.

A dummy line disposed closest to the display area from among the plurality of dummy lines may be spaced at least 50 micrometers apart from the display area.

An end of the dummy line disposed closest to the display area may be spaced apart from the display area in a second direction, which crosses the first direction.

Ends of some dummy lines from among the plurality of dummy lines may be spaced apart from the display area in the first direction.

A distance that the ends of the some dummy lines are spaced apart from the display area may correspond to a first-direction length of one of the plurality of pixels.

Some dummy lines from among the plurality of dummy lines may extend beyond points where the plurality of signal lines are electrically connected to the plurality of pixels in the first direction.

The pixel circuit of each of the plurality of pixels may include a thin-film transistor electrically connected to the at least one light-emitting diode. The thin-film transistor may include a semiconductor pattern, a gate electrode disposed on the semiconductor pattern, and a source electrode and a drain electrode disposed on the gate electrode.

Some dummy lines from among the plurality of dummy lines may be disposed in a same layer as the gate electrode.

A portion of the plurality of dummy lines may be disposed in a same layer as the source electrode and the drain electrode, and another portion of the plurality of dummy lines may be disposed in a same layer as the gate electrode.

Two dummy lines adjacent to each other from among the plurality of dummy lines may be disposed in different layers from one another.

The display apparatus may further include a plurality of signal supply lines configured to supply, to the plurality of signal lines, signals for driving the plurality of pixels. At least some signal supply lines from among the plurality of signal supply lines may be electrically connected to the plurality of dummy lines.

A display apparatus includes a substrate including a display area and a peripheral area. A plurality of pixels is disposed in the display area and each of the plurality of pixels includes at least one light-emitting diode and at least one pixel circuit. A plurality of signal lines is electrically connected to the plurality of pixels and each of the plurality of signal lines extends in a first direction. A plurality of dummy lines is disposed adjacent to the plurality of signal lines and within the peripheral area, spaced apart from the plurality of pixels. Each of the plurality of dummy lines extends in the first direction. A distance between a dummy line disposed closest to the display area from among the plurality of dummy lines and a pixel disposed closest to the peripheral area from among the plurality of pixels is at least 50 micrometers.

The distance may be a distance measured in the first direction.

The distance may be a distance measured in a second direction, which crosses the first direction.

At least some dummy lines from among the plurality of dummy lines may extend beyond points where the plurality of signal lines are electrically connected to the plurality of pixels in the first direction.

Ends of at least some dummy lines from among the plurality of dummy lines may be spaced apart from one another in the first direction.

The distance may correspond to a length of a pixel from among the plurality of pixels, the length being measured in the first direction or in a second direction crossing the first direction.

An electronic device includes a display apparatus and a processor configured to drive the display apparatus. The display apparatus includes a substrate including a display area and a peripheral area. A plurality of pixels is disposed in the display area and each of the plurality of pixels includes at least one light-emitting diode and at least one pixel circuit. A plurality of signal lines is electrically connected to light-emitting diodes of the plurality of pixels. A plurality of dummy lines is disposed adjacent to the plurality of signal lines and within the peripheral area and is separated from the plurality of pixels. Ends of at least some dummy lines from among the plurality of dummy lines are spaced apart from one another in a first direction in which each of the plurality of dummy lines extend.

### BRIEF DESCRIPTION OF THE DRAWINGS

The above and other aspects and features of certain embodiments of the disclosure will be more apparent from the following description taken in conjunction with the accompanying drawings, in which:

FIG. 1 is a block diagram of an electronic device according to an embodiment;

FIGS. 2, 3, and 4 are schematic diagrams of electronic devices according to various embodiments;

FIG. 5 is a schematic plan view of a display apparatus according to an embodiment;

FIG. 6 is an equivalent circuit diagram of a pixel of a display apparatus according to an embodiment;

FIG. 7 is a cross-sectional view of a display area of a display apparatus according to an embodiment;

FIG. 8 is a plan view of a display apparatus according to an embodiment;

FIG. 9 is an enlarged plan view of a display apparatus according to an embodiment;

FIG. 10 is an enlarged plan view of a display apparatus according to an embodiment;

FIG. 11 is an enlarged plan view of a display apparatus according to an embodiment;

FIG. 12 is an enlarged plan view of a display apparatus according to an embodiment;

FIG. 13 is a cross-sectional view of a display apparatus according to an embodiment; and

FIGS. 14A, 14B, and 14C are cross-sectional views of a display apparatus according to an embodiment.

### DETAILED DESCRIPTION

Reference will now be made in detail to embodiments, examples of which are illustrated in the accompanying drawings, wherein like reference numerals may refer to like elements throughout the specification and the drawings. In this regard, the present embodiments may have different forms and should not necessarily be construed as being limited to the descriptions set forth herein. Accordingly, the embodiments explain aspects of the present description. As used herein, the term "and/or" includes any and all combinations of one or more of the associated listed items. Throughout the disclosure, the expression "at least one of a, b, or c" indicates only a, only b, only c, both a and b, both a and c, both b and c, all of a, b, and c, or variations thereof.

The disclosure can be modified in various ways and has various embodiments. Certain embodiments are illustrated in the drawings and described in detail in the detailed description. The effects and features of the disclosure and a method for achieving them will become clear with reference to embodiments described in detail below together with the drawings. The disclosure is not necessarily limited to the embodiments disclosed below and may be implemented in various forms.

Hereinafter, embodiments will be described in detail with reference to the accompanying drawings. When describing with reference to the drawings, identical or corresponding components may be given the same drawing reference numerals and to the extent that an element is not described in detail with respect to this figure, it may be understood that the element is at least similar to a corresponding element that has been described elsewhere within the present disclosure.

In this specification, the terms "first," "second," etc. are not necessarily used in a limiting sense but may be used for the purpose of distinguishing one component from another component.

In this specification, singular expressions may include plural expressions unless the context clearly indicates otherwise.

In this specification, terms such as "include" or "have" mean that a feature or component described in the specification is present, and do not necessarily exclude the possibility that one or more other features or components may be added.

In this specification, when it is described that a part such as a film, area, or component is on or above another part, it includes not only the case where it is directly on top of the other part, but also the case where another film, area, component, etc. is located therebetween.

While each drawing may represent one or more particular embodiments of the present disclosure, drawn to scale, such that the relative lengths, thicknesses, and angles can be inferred therefrom, it is to be understood that the present invention is not necessarily limited to the relative lengths, thicknesses, and angles shown. Changes to these values may be made within the spirit and scope of the present disclosure, for example, to allow for manufacturing limitations and the like.

In some embodiments, where the implementation is otherwise feasible, specific process sequences may be performed in a different order than described. For example, two processes described sequentially may be performed substantially simultaneously, or may proceed in the reverse order from that described.

In this specification, "A and/or B" indicates the case of A, B, or both A and B. In this specification, "at least one of A or B" indicates the case where it is A, or B, or both A and B.

In this specification, when it is stated that a film, area, component, etc. are (e.g., electrically) connected, it includes cases where the film, area, or component is directly (e.g., electrically) connected, and/or cases where other film, area, or component is located between the film, area, or component and is indirectly (e.g., electrically) connected.

The x-axis, y-axis, and z-axis are not necessarily limited to the three axes on the orthogonal coordinate system, and can be interpreted in a broad sense that includes them. For example, the x-axis, y-axis, and z-axis may be orthogonal to each other, but they might not be.

Embodiments of the present disclosure relate to a display apparatus designed to increase pixel reliability by mitigating failures caused by static electricity in signal lines. In such displays, each pixel may include a light-emitting diode and a driving pixel circuit. Signal lines transmit data and power to these circuits, but static electricity may inadvertently accumulate and discharge through these lines, potentially damaging pixels, especially those connected to signal lines at the outermost edges of the display. To address this, embodiments of the present disclosure introduce dummy lines arranged in the peripheral area of the substrate. These dummy lines do not connect to pixels but act as sacrificial wiring to absorb and dissipate static charges safely, thereby preventing harmful discharge into adjacent pixels.

The arrangement of dummy lines is carefully engineered. They extend parallel to the signal lines, are disposed at prescribed intervals, and are separated from the display area by a minimum distance, often on the order of 50 micrometers or more. This spacing ensures that when static electricity is released from the ends of the dummy lines, it does not flow into the pixels. Multiple dummy lines may be used, with staggered or offset end positions in the line’s extension direction, and some dummy lines may extend beyond the connection points of signal lines to the pixels, while others terminate beforehand. The relative distances between dummy lines may be set to correspond to the dimensions of a single pixel, providing design uniformity and predictable electrical behavior.

Embodiments of the present disclosure may be implemented within various layers of the display structure. Dummy lines may be disposed in the same conductive layers as gate electrodes, source/drain electrodes, or other signal supply lines. Their positioning and layering provide both electrical isolation and effective dissipation of electrostatic charge. These concepts can be applied across many electronic devices that employ light-emitting diode displays, including smartphones, tablets, televisions, computer monitors, wearables, vehicle displays, and appliances. By integrating dummy lines into the peripheral area of the display apparatus, embodiments of the present disclosure may enhance durability, reduces defect rates, and ensures higher reliability in manufacturing and long-term operation.

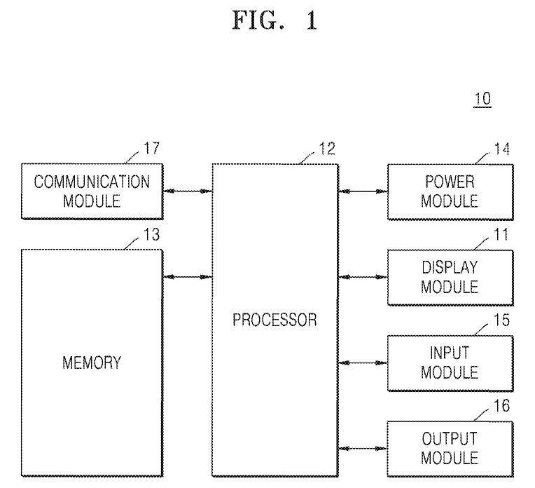

FIG. 1 is a block diagram of an electronic device according to an embodiment. Referring to FIG. 1, an electronic device 10 may include a display module 11, a processor 12, a memory 13, and a power module 14.

The processor 12 may include at least one of a central processing unit (CPU), an application processor (AP), a graphics processing unit (GPU), a communication processor (CP), an image signal processor (ISP), and a controller. In an embodiment, the processor 12 may be split into two or more parts from a functional or structural standpoint. For example, the processor 12 may include a main processor in the form of a first driving chip including a CPU, and an auxiliary processor in the form of a second driving chip including a controller configured to receive an image signal from the main processor and process the image signal to conform to the interface specifications of the display module 11.

The memory 13 may include at least one of non-volatile memory and volatile memory. The memory 13 may store data information for an operation of the processor 12 or the display module 11. When the processor 12 executes an application stored in the memory 13, an image data signal and/or an input control signal may be transmitted to the display module 11, and the display module 11 may process the received signal and output image information through a display screen.

The power module 14 may include a power supply module, such as a power adapter or a battery device, and a power conversion module, which converts power supplied by the power supply module to generate power required an operation of the electronic device 10. The power conversion by the power conversion module may include, but is not necessarily limited to, direct current (DC)-DC conversion, alternating current (AC)-DC conversion, and DC-AC conversion.

The electronic device 10 may further include an input module 15, a non-video output module 16 and/or a communication module 17.

The input module 15 may provide input information to the processor 12 and/or the display module 11. The input module 15 may include various sensor modules as well as physical buttons, a keyboard, and a microphone. Examples of the sensor modules may include not only touch sensors, pressure sensors, distance sensors, location sensors, digitizers, motion recognition sensors, camera sensors, photodetectors, photoelectric conversion sensors, temperature sensors, but also biosensors, such as blood pressure sensors, blood sugar sensors, electrocardiogram sensors, and heart rate sensors.

The non-video output module 16 may receive information other than video from the processor 12 and provide the received information to the user. Examples of the non-video output module 16 include audio modules, haptic modules, light-emitting modules, etc., and may include other functional modules unique to electronic devices (e.g., a cooling module of a refrigerator).

The communication module 17 is a module responsible for transmitting and receiving information between the electronic device 10 and an external device, and may include a reception unit and a transmission unit. The communication module 17 may include various wireless communication modules, such as a mobile communication module, a Wireless Fidelity (Wi-Fi) module, a Bluetooth module, or various wired communication modules.

At least one of the elements of the electronic device 10 described above may be included in a display apparatus. In addition, some of individual modules functionally included within a module may be included within the display apparatus, while others may be provided separately from the display apparatus. For example, the display apparatus may include the display module 11, and the processor 12, the memory 13, and the power module 14 may be provided in the form of other devices within the electronic device 10 other than the display apparatus. In an example, the power module 14 may be provided within the display apparatus and may supply power to the processor 12 and the memory 13 provided within the electronic device 10, which is not the display apparatus. However, the disclosure is not necessarily limited to the examples described above.

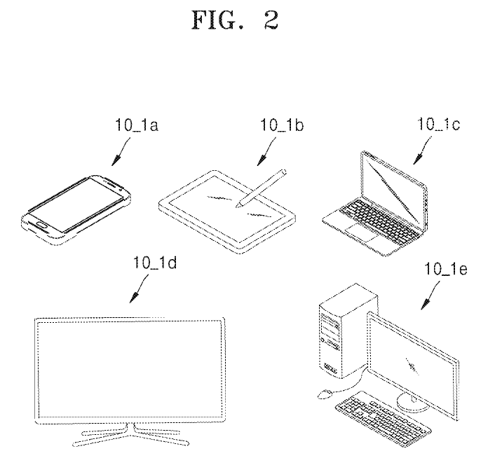

FIGS. 2-4 are schematic diagrams of electronic devices according to various embodiments. FIGS. 2-4 show examples of various electronic devices to which display apparatuses according to embodiments are applied.

FIG. 2 shows examples of electronic devices, including a smartphone 10_1a, a tablet computer 10_1b, a laptop/notebook computer 10_1c, a television (TV) 10_1d, and a computer monitor 10_1e.

The smartphone 10_1a may include an input module, such as a touch sensor, and a communication module in addition to the display module 11. The smartphone 10_1a may process information received through a communication module or other input modules and display the information through a display module of the display apparatus.

The tablet computer 10_1b, the laptop/notebook computer 10_1c, the TV 10_1d, and the computer monitor 10_1e may also include a display module and an input module, similar to the smartphone 10_1a, and may additionally include a communication module in some cases.

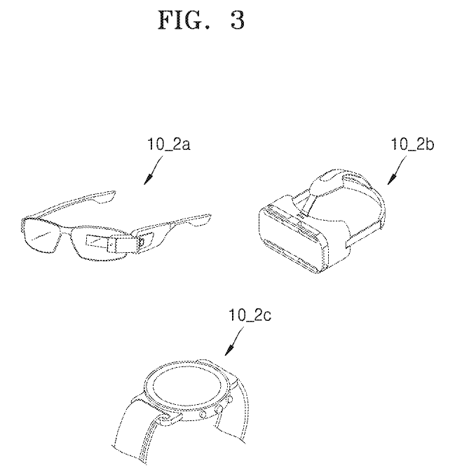

FIG. 3 shows an example in which an electronic device including a display module is applied to a wearable electronic device. The wearable electronic device may be smart glasses 10_2a, a head-mounted display 10_2b, a smart watch 10_2c, etc.

The smart glasses 10_2a and the head-mounted display 10_2b may include a display module which emits a display image and a reflector which reflects an emitted display screen and provides the reflected display screen to the user's eyes, thereby providing a virtual reality or augmented reality screen to the user.

The smart watch 10_2c may include a biometric sensor as an input device and may provide biometric information recognized by the biometric sensor to the user through a display module.

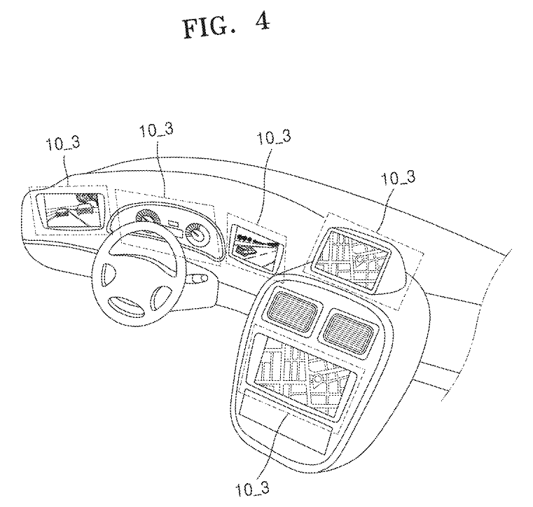

FIG. 4 shows an example in which an electronic device including a display module is applied to a vehicle. For example, an electronic device 10_3 may be applied to a dashboard, center fascia, etc. of a vehicle, or may be applied to a center information display (CID) disposed on a dashboard of a vehicle or a room mirror display replacing a side-view mirror.

Electronic devices to which display apparatuses according to embodiments are applied may include not only devices which mainly display screens, such as billboards, electronic boards, and portable game consoles, but also various home appliances which display information through display modules, such as refrigerators, washing machines, dryers, air conditioners, and robot vacuum cleaners. In addition, when the display module has a function of transmitting light, the display module may be applied to electronic devices, such as smart windows or transparent display apparatuses which display a background and a display image together. Types of the electronic devices according to embodiments are not necessarily limited to the examples described above, and application to other various electronic devices not described may also be possible.

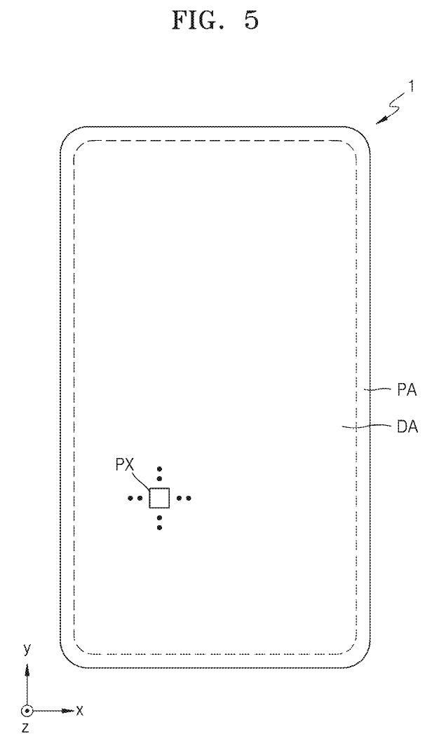

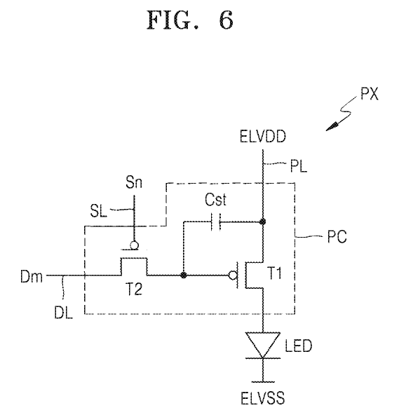

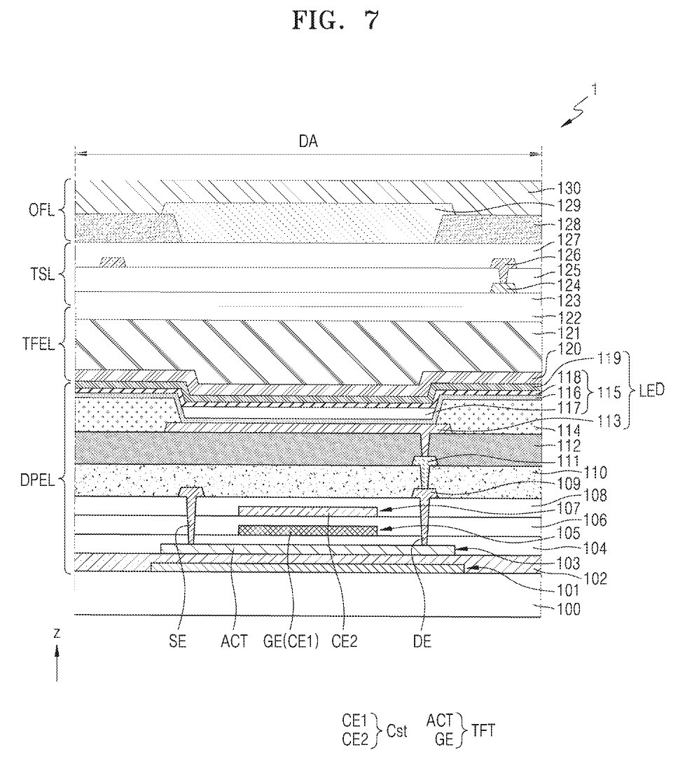

FIG. 5 is a schematic plan view of a display apparatus according to an embodiment. FIG. 6 is an equivalent circuit diagram of a pixel of a display apparatus according to an embodiment. FIG. 7 is a cross-sectional view of a display area of a display apparatus according to an embodiment.

Referring to FIG. 5, a display apparatus 1 may include a display area DA and a peripheral area PA outside the display area DA. For example, the display apparatus 1 may define the display area DA and the peripheral area PA outside the display area DA. For example, the display apparatus 1 may include a substrate 100 (see FIG. 7), and the display area DA and the peripheral area PA may be defined on the substrate 100. For example, the substrate 100 of the display apparatus 1 (see FIG. 7) may include the display area DA and the peripheral area PA outside the display area DA.

A pixel PX may be disposed in the display area DA. The pixel PX may include at least one light-emitting diode LED and a pixel circuit PC for driving the light-emitting diode LED (see FIG. 6). The light-emitting diode LED driven by the pixel circuit PC may emit light of a specific color (i.e. wavelength range). The display apparatus 1 may provide an image and/or a video through light emitted from a plurality of light-emitting diodes LED respectively provided in a plurality of pixels PX. In an embodiment, the pixel PX may include a plurality of grouped sub-pixels. In an embodiment, a sub-pixel may be provided with a corresponding light-emitting diode and a corresponding sub-pixel circuit. In an embodiment, the light-emitting diodes respectively provided in the plurality of sub-pixels grouped into one pixel PX may emit light of different colors (i.e., wavelength ranges). The peripheral area PA, which is a non-display area, and signal lines and/or voltage lines for driving light-emitting diodes may be disposed in the peripheral area PA.

FIG. 5 shows that the display apparatus 1 and the display area DA have an approximately rectangular shape with rounded corners, but the disclosure is not necessarily limited thereto. The display apparatus 1 and/or the display area DA may have various shapes, such as polygonal, circular, oval, or irregular shapes.

Referring to FIG. 6, the pixel circuit PC may be connected to the light-emitting diode LED to implement emission of the pixels PX. In an embodiment, the light-emitting diode LED may be an organic light-emitting diode. The pixel circuit PC may include a first transistor T1, a second transistor T2, and a storage capacitor Cst. In an embodiment, the first transistor T1 may be a driving transistor and the second transistor T2 may be a switching transistor. The second transistor T2 may be connected to a scan line SL and a data line DL and may be configured to transmit a data signal Dm input through the data line DL to the first transistor T1 according to a scan signal Sn input through the scan line SL.

The storage capacitor Cst may be connected to the second transistor T2 and a driving voltage line PL, and may store a voltage corresponding to a voltage difference between a voltage received from the second transistor T2 and a driving voltage ELVDD supplied to the driving voltage line PL.

The first transistor T1 may be connected to the driving voltage line PL and the storage capacitor Cst, and may control a driving current flowing to the light-emitting diode LED from the driving voltage line PL in response to a value of the voltage stored in the storage capacitor Cst. The light-emitting diode LED may emit light with a certain brightness, depending on the driving current.

The pixel circuit PC is not necessarily limited to the number of thin-film transistors and capacitors and the circuit design described with reference to FIG. 6, and the number of thin-film transistors and capacitors and the circuit design may be changed in various ways.

Referring to FIG. 7, the display apparatus 1 may include a display element layer DPEL, a thin-film encapsulation layer TFEL, a touch sensing layer TSL, and an optical function layer OFL. The display element layer DPEL, the thin-film encapsulation layer TFEL, the touch sensing layer TSL, and the optical function layer OFL may be sequentially disposed on the substrate 100.

The display element layer DPEL may include the light-emitting diode LED and a thin-film transistor TFT connected to the light-emitting diode LED. In an embodiment, FIG. 7 may schematically show a portion of the pixel circuit PC described with reference to FIG. 6. For example, the thin-film transistor TFT connected to the light-emitting diode LED may correspond to a transistor connected to the light-emitting diode LED from among the transistors shown in FIG. 6, such as the first transistor T1.

The substrate 100 may include a glass material or a polymer resin. In an embodiment, the substrate 100 may include a laminated structure of a base layer including a polymer resin and a barrier layer including an inorganic insulating material. The polymer resin may include at least one of materials, such as polyethersulfone, polyarylate, polyetherimide, polyethylene naphthalate, polyethylene terephthalate, polyphenylene sulfide, polyimide, polycarbonate, cellulose triacetate, and cellulose acetate propionate. The inorganic insulating material may include at least one of materials, such as silicon oxide (SiO₂) and silicon nitride (SiNₓ).

A first conductive layer 101 may be disposed on the substrate 100. In an embodiment, the first conductive layer 101 may include a power line and/or a signal line. In an embodiment, the first conductive layer 101 may be disposed under a semiconductor layer 103, such as an active pattern ACT, to block radio waves and/or light originating from a lower portion of the display apparatus 1 from being transmitted to the active pattern ACT. In an embodiment, the first conductive layer 101 may include a metal (e.g., having light-shielding properties). In an embodiment, the first conductive layer 101 may include at least one of materials, such as aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), and copper (Cu), and may have a single- or multi-layer structure.

A first insulating layer 102 may be disposed on the first conductive layer 101. The first insulating layer 102 may entirely cover the first conductive layer 101. The first insulating layer 102 may have a flat upper surface. The first insulating layer 102 may include an inorganic insulating material. In an embodiment, the first insulating layer 102 may include at least one of materials, such as SiO₂, SiNₓ, silicon oxynitride (SiON), aluminum oxide (Al₂O₃), titanium oxide (TiO₂), tantalum oxide (Ta₂O₅), hafnium oxide (HfO₂), and zinc oxide (ZnO₂), and may have a single- or multi-layer structure. In an embodiment, the first insulating layer 102 may be a buffer layer.

The thin-film transistor TFT may be disposed on the first insulating layer 102. The thin-film transistor TFT may include the active pattern ACT and a gate electrode GE.

The semiconductor layer 103 may be disposed on the first insulating layer 102. The semiconductor layer 103 may include the active pattern ACT. The active pattern ACT may include a source region overlapping a source electrode SE, a drain region overlapping a drain electrode DE, and a channel region between the source region and the drain region. The channel region may overlap the gate electrode GE. The source region and the drain region may be regions doped with impurities (e.g., dopants).

A second insulating layer 104 may be disposed on the semiconductor layer 103. The second insulating layer 104 may cover the semiconductor layer 103, for example, the active pattern ACT. The second insulating layer 104 may include an inorganic insulating material. In an embodiment, the second insulating layer 104 may include at least one of materials, such as SiO₂, SiNₓ, SiON, Al₂O₃, TiO₂, Ta₂O₅, HfO₂, and ZnO₂, and may have a single- or multi-layer structure. In an embodiment, the second insulating layer 104 may be a first gate insulating layer.

The storage capacitor Cst may be disposed on the second insulating layer 104. The storage capacitor Cst may include a first capacitor electrode CE1 and a second capacitor electrode CE2. The first capacitor electrode CE1 and the second capacitor electrode CE2 may overlap each other, and the second capacitor electrode CE2 may be disposed on the first capacitor electrode CE1.

A second conductive layer 105 may be disposed on the second insulating layer 104. The second conductive layer 105 may include the gate electrode GE of the thin-film transistor TFT and the first capacitor electrode CE1 of the storage capacitor Cst. In an embodiment, the gate electrode GE and the first capacitor electrode CE1 may be provided integrally as a single body, as shown in FIG. 7. In an embodiment, the gate electrode GE and the first capacitor electrode CE1 may be provided separately. In an embodiment, the second conductive layer 105 may include at least one of materials, such as Al, Pt, Pd, Ag, Mg, Au, Ni, Nd, Ir, Cr, Ca, Mo, Ti, W, and Cu, and may have a single- or multi-layer structure.

A third insulating layer 106 may be disposed on the second conductive layer 105. The third insulating layer 106 may cover the second conductive layer 105, for example, the gate electrode GE and the first capacitor electrode CE1. The third insulating layer 106 may include an inorganic insulating material. In an embodiment, the third insulating layer 106 may include at least one of materials, such as SiO₂, SiNₓ, SiON, Al₂O₃, TiO₂, Ta₂O₅, HfO₂, and ZnO₂, and may have a single- or multi-layer structure. In an embodiment, the third insulating layer 106 may be a second gate insulating layer.

A third conductive layer 107 may be disposed on the third insulating layer 106. The third conductive layer 107 may include the second capacitor electrode CE2. The second capacitor electrode CE2 may overlap the first capacitor electrode CE1. In an embodiment, the third conductive layer 107 may include at least one of materials, such as Al, Pt, Pd, Ag, Mg, Au, Ni, Nd, Ir, Cr, Ca, Mo, Ti, W, and Cu, and may have a single- or multi-layer structure.

A fourth insulating layer 108 may be disposed on the third conductive layer 107. The fourth insulating layer 108 may cover the third conductive layer 107, for example, the second capacitor electrode CE2. The fourth insulating layer 108 may include an inorganic insulating material. In an embodiment, the fourth insulating layer 108 may include at least one of materials, such as SiO₂, SiNₓ, SiON, Al₂O₃, TiO₂, Ta₂O₅, HfO₂, and ZnO₂, and may have a single- or multi-layer structure. In an embodiment, the fourth insulating layer 108 may be an interlayer insulating layer.

A fourth conductive layer 109 may be disposed on the fourth insulating layer 108. The fourth conductive layer 109 may include the source electrode SE and the drain electrode DE. The source electrode SE may overlap the source region of the active pattern ACT. The source electrode SE may be connected to the active pattern ACT (e.g., source region) through an opening defined in the second to fourth insulating layers 104, 106, and 108. The drain electrode DE may overlap the drain region of the active pattern ACT. The drain electrode DE may be connected to the active pattern ACT (e.g., drain region) through an opening defined in the second to fourth insulating layers 104, 106, and 108. In an embodiment, the fourth conductive layer 109 may include at least one of materials, such as Al, Pt, Pd, Ag, Mg, Au, Ni, Nd, Ir, Cr, Ca, Mo, Ti, W, and Cu, and may have a single- or multi-layer structure.

FIG. 7 illustrates an embodiment in which the second to fourth insulating layers 104, 106, and 108 each have a flat upper surface. However, the disclosure is not necessarily limited thereto, and the second to fourth insulating layers 104, 106, and 108 may have an upper surface shape (e.g., unevenness) corresponding to a shape of a layer disposed below each.

It is to be understood that in this and other figures, when a layer is shown as being disposed directly on another layer it may indeed be directly disposed on that other layer, or an intervening layer may be present therebetween. Similarly, when elements are shown as being directly touching one another, they may indeed be directly touching one another or intervening elements may be present therebetween.

A fifth insulating layer 110 may be disposed on the fourth conductive layer 109. The fifth insulating layer 110 may cover the fourth conductive layer 109, for example, the source electrode SE and the drain electrode DE. The fifth insulating layer 110 may have a flat upper surface. The fifth insulating layer 110 may include an organic insulating material. In an embodiment, the fifth insulating layer 110 may include at least one of a general-purpose polymer, such as benzocyclobutene, polyimide, hexamethyldisiloxane, polymethylmethacrylate, or polystyrene, a polymer derivative having a phenol-based group, an acryl-based polymer, an imide-based polymer, an aryl ether-based polymer, an amide-based polymer, a fluorinated polymer, a p-xylene-based polymer, or a vinyl alcohol-based polymer, and may have a single- or multi-layer structure. In an embodiment, the fifth insulating layer 110 may be a first via layer.

A fifth conductive layer 111 may be disposed on the fifth insulating layer 110. The fifth conductive layer 111 may include the fourth conductive layer 109, for example, a contact metal connecting the drain electrode DE to a first electrode 113 of the light-emitting diode LED. The fifth conductive layer 111 may also include gate electrodes, signal lines, power lines, etc. of other transistors. In an embodiment, the fifth conductive layer 111 may include at least one of materials, such as Al, Pt, Pd, Ag, Mg, Au, Ni, Nd, Ir, Cr, Ca, Mo, Ti, W, and Cu, and may have a single- or multi-layer structure.

A sixth insulating layer 112 may be disposed on the fifth conductive layer 111. The sixth insulating layer 112 may cover the fifth conductive layer 111. The sixth insulating layer 112 may have a flat upper surface. The sixth insulating layer 112 may include an organic insulating material. In an embodiment, the sixth insulating layer 112 may include at least one of a general-purpose polymer, such as benzocyclobutene, polyimide, hexamethyldisiloxane, polymethylmethacrylate, or polystyrene, a polymer derivative having a phenol-based group, an acryl-based polymer, an imide-based polymer, an aryl ether-based polymer, an amide-based polymer, a fluorinated polymer, a p-xylene-based polymer, or a vinyl alcohol-based polymer, and may have a single- or multi-layer structure. In an embodiment, the sixth insulating layer 112 may be a second via layer.

The light-emitting diode LED may be disposed on the sixth insulating layer 112. The light-emitting diode LED may include the first electrode 113 and a second electrode 119 facing each other, and an intermediate layer 115 between the first electrode 113 and the second electrode 119. In an embodiment, the first electrode 113 of the light-emitting diode LED may correspond to the anode, and the second electrode 119 may correspond to the cathode.

The first electrode 113 of the light-emitting diode LED may be disposed on the sixth insulating layer 112. The first electrode 113 may be connected to the fifth conductive layer 111 through an opening defined in the sixth insulating layer 112. The first electrode 113 may be (e.g. electrically) connected to the thin-film transistor TFT via the fifth conductive layer 111 and the drain electrode DE. The first electrode 113 may include a conductive oxide, such as indium tin oxide (ITO), indium zinc oxide (IZO), zinc oxide (ZnO), In₂O₃, indium gallium oxide (IGO), or aluminum zinc oxide (AZO). The first electrode 113 may include a reflective film including Ag, Mg, Al, Pt, Pd, Au, Ni, Nd, Ir, Cr, or a compound thereof. However, a composition and materials of the first electrode 113 are not necessarily limited thereto, and may be modified in various ways.

A pixel-defining layer 114 may be disposed on the sixth insulating layer 112. The pixel-defining layer 114 may cover an edge of the first electrode 113. For example, the pixel-defining layer 114 may be opened and may expose a central portion of the first electrode 113. A size and shape of an emission area of the light-emitting diode LED may be determined by the opening defined in the pixel-defining layer 114. In an embodiment, the pixel-defining layer 114 may include an organic insulating material. In an embodiment, the pixel-defining layer 114 may include at least one of a general-purpose polymer, such as benzocyclobutene, polyimide, hexamethyldisiloxane, polymethylmethacrylate, or polystyrene, a polymer derivative having a phenol-based group, an acryl-based polymer, an imide-based polymer, an aryl ether-based polymer, an amide-based polymer, a fluorinated polymer, a p-xylene-based polymer, or a vinyl alcohol-based polymer, and may have a single- or multi-layer structure.

The intermediate layer 115 may be disposed on the first electrode 113. The intermediate layer 115 may include first and second common layers 116 and 118 disposed on the pixel-defining layer 114, and an emission layer 117 disposed within the opening defined in the pixel-defining layer 114. The first common layer 116 may be disposed on the second common layer 118. In an embodiment, the first common layer 116 may be disposed on the pixel-defining layer 114, the emission layer 117 may be disposed within the opening defined in the pixel-defining layer 114 on the first common layer 116, and the second common layer 118 may be disposed on the first common layer 116 to cover the emission layer 117. For example, the emission layer 117 may be disposed within the opening defined in the pixel-defining layer 114 and may be located between the first common layer 116 and the second common layer 118.

The emission layer 117 may include a small molecule or large molecule material which emits light of a specific color when current flows. The first common layer 116 may include an electron transport layer (ETL) and/or an electron injection layer (EIL). The second common layer 118 may include a hole transport layer (HTL) and/or a hole injection layer (HIL). In some embodiments, the first common layer 116 or the second common layer 118 may be omitted. In some embodiments, locations of the first common layer 116 and the second common layer 118 may be switched.

The second electrode 119 may be disposed on the intermediate layer 115. For example, the second electrode 119 may be disposed on the second common layer 118. The second electrode 119 may be disposed to entirely cover the intermediate layer 115. The second electrode 119 may include a conductive material. For example, the second electrode 119 may include a transparent layer (or a semi-transparent layer) including Ag, Mg, Al, Pt, Pd, Au, Ni, Nd, Ir, Cr, Li, Ca, or an alloy thereof. Alternatively, the second electrode 119 may further include a layer including an oxide, such as ITO, IZO, ZnO, or In₂O₃, on the transparent layer (or semi-transparent layer) including the materials described above.

The thin-film encapsulation layer TFEL may be disposed on the second electrode 119 and may entirely cover the light-emitting diode LED. The thin-film encapsulation layer TFEL may include at least one inorganic layer and at least one organic layer. In an embodiment, the thin-film encapsulation layer TFEL may include a first inorganic encapsulation layer 120, a second inorganic encapsulation layer 122, and an organic encapsulation layer 121 disposed between the first inorganic encapsulation layer 120 and the second inorganic encapsulation layer 122. In an embodiment, the first inorganic encapsulation layer 120 and the second inorganic encapsulation layer 122 may have an upper surface shape (e.g., unevenness) corresponding to the shape of the layer disposed under each. In an embodiment, the organic encapsulation layer 121 may have a flat upper surface.

The first inorganic encapsulation layer 120 and/or the second inorganic encapsulation layer 122 may include at least one of materials, such as SiO₂, SiNₓ, SiON, Al₂O₃, TiO₂, Ta₂O₅, HfO₂, and ZnO₂, and may have a single- or multi-layer structure. The organic encapsulation layer 121 may include a polymer-based material. Examples of the polymer-based material include silicone-based resins, acryl-based resins, epoxy-based resins, polyimides, and polyethylene.

The touch sensing layer TSL may be disposed on the thin-film encapsulation layer TFEL. The touch sensing layer TSL may include a touch electrode layer for detecting external input, such as a touch event, and a touch insulation layer between the electrode layers. The touch sensing layer TSL may include a first touch insulating layer 123, a first touch electrode layer 124, a second touch insulating layer 125, a second touch electrode layer 126, and a third touch insulating layer 127.

The first touch insulating layer 123 may be disposed on the thin-film encapsulation layer TFEL, for example, the second inorganic encapsulation layer 122 of the thin-film encapsulation layer TFEL. The first touch electrode layer 124 may be disposed on the first touch insulating layer 123. The second touch insulating layer 125 may be disposed on the first touch electrode layer 124 and may cover the first touch electrode layer 124. The second touch electrode layer 126 may be disposed on the second touch insulating layer 125. The third touch insulating layer 127 may be disposed on the second touch electrode layer 126 and may cover the second touch electrode layer 126. The second touch electrode layer 126 may be connected to the first touch electrode layer 124 through an opening defined in the second touch insulating layer 125. In an embodiment, the second touch electrode layer 126 may include a sensing electrode and the first touch electrode layer 124 may include a bridge electrode.

In an embodiment, the first touch insulating layer 123 may include an inorganic insulating material. In an embodiment, the first touch insulating layer 123 may include at least one of materials, such as SiO₂, SiNₓ, SiON, Al₂O₃, TiO₂, Ta₂O₅, HfO₂, and ZnO₂, and may have a single- or multi-layer structure.

In an embodiment, the second touch insulating layer 125 and the third touch insulating layer 127 may include an organic insulating material. In an embodiment, the second touch insulating layer 125 and/or the third touch insulating layer 127 may include an acryl-based organic insulating material. In an embodiment, the second touch insulating layer 125 and/or the third touch insulating layer 127 may have a flat upper surface.

The first touch electrode layer 124 and the second touch electrode layer 126 might not entirely overlap the emission area of the light-emitting diode LED. In an embodiment, the first touch electrode layer 124 and the second touch electrode layer 126 might not overlap the emission layer 117 of the light-emitting diode LED. For example, the first touch electrode layer 124 and the second touch electrode layer 126 may have an opening which overlaps the emission area or the emission layer 117 of the light-emitting diode LED.

The optical function layer OFL may be disposed on the touch sensing layer TSL. The optical function layer OFL may include a light-shielding layer 128, a color filter 129, and an overcoat layer 130. The overcoat layer 130 may cover the light-shielding layer 128 and the color filter 129 and may have a flat upper surface.

The light-shielding layer 128 may be disposed on the touch sensing layer TSL, for example, the third touch insulating layer 127. The light-shielding layer 128 may include a light-shielding material and may cover the first and second touch electrode layers 124 and 126 to prevent the first and second touch electrode layers 124 and 126 from reflecting external light and being visible to the user. However, the light-shielding layer 128 is not necessarily limited to these effects and may provide various other effects. In addition, the light-shielding layer 128 may be opened to allow light emitted from the light-emitting diode LED to pass therethrough. The opening defined in the light-shielding layer 128 may overlap the light-emitting diode LED, for example, the emission layer 117.

The color filter 129 may be disposed on the light-shielding layer 128. The color filter 129 may overlap the opening defined in the light-shielding layer 128, and a portion of the color filter 129 may be positioned within the opening defined in the light-shielding layer 128. The color filter 129 may transmit light of a color (or wavelength range) corresponding to the light emitted from the emission layer 117 of the light-emitting diode LED. For example, when the emission layer 117 of the light-emitting diode LED emits red light, the color filter 129 may be provided to transmit light in the red wavelength range.

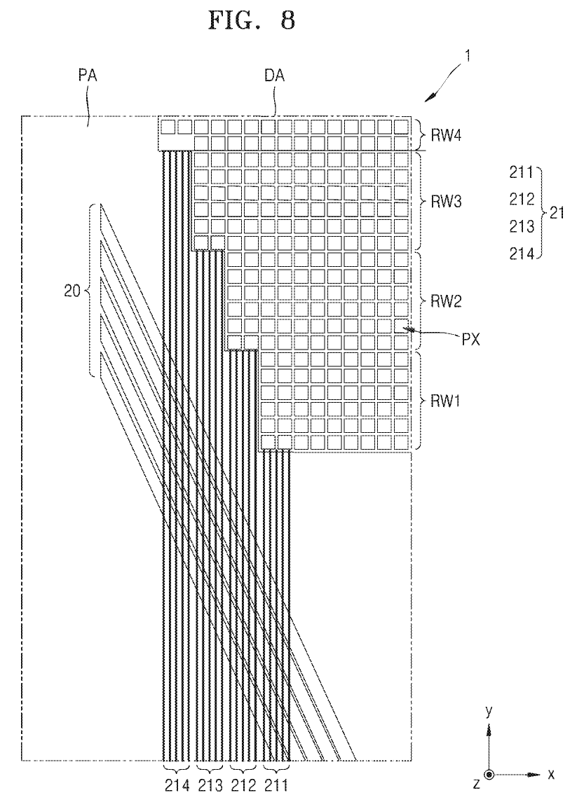

FIG. 8 is a plan view of a display apparatus according to an embodiment. FIG. 8 may be an enlarged view of a curved portion of the display apparatus 1. For example, FIG. 8 may be an enlarged view of a round corner of the display apparatus 1 shown in FIG. 5.

Referring to FIG. 8, a plurality of pixels PX of the display apparatus 1 may be arranged in a row in the display area DA. In an embodiment, the display apparatus 1 may include a first row RW1, a second row RW2, a third row RW3, and a fourth row RW4 of the pixels PX. The first to fourth rows RW1, RW2, RW3, and RW4 of the pixels PX may be arranged in a first direction (e.g., +y direction or -y direction). Each of the rows of the pixels PX may include a plurality of sub-rows of pixels PX extending in a second direction (e.g., a +x direction or a -x direction) crossing the first direction (e.g., the +y direction or the -y direction). In an embodiment, the first row RW1 of the pixels PX may include six sub-rows. In an embodiment, the second row RW2 of the pixels PX may include six sub-rows. In an embodiment, the third row RW3 of the pixels PX may include six sub-rows. Although partially shown in FIG. 8, in an embodiment, the fourth row RW4 of the pixels PX may include six sub-rows.

The disclosure is not necessarily limited to a specific number of rows, and the display apparatus 1 may include M rows of pixels PX (where M is a positive integer other than 4). The disclosure is not necessarily limited to a specific number of sub-rows included in one pixel PX row, and one row of pixels PX may include N sub-rows (where N is a positive integer other than 6). It is noted that M may indeed be 4 and N may indeed be 6, as is described elsewhere in the instant specification, but this particular description applies mainly to embodiments where M is not 4 and N is not 6.

Rows of pixels PX may be shifted along one direction, for example, a second direction (e.g., the +x direction or the -x direction), by the curvature of the display apparatus 1 and the curvature of the display area DA. In an embodiment, the second row RW2 may be shifted in the -x direction with respect to the first row RW1, and a portion of the second row RW2 may protrude beyond an edge of the first row RW1. In an embodiment, the third row RW3 may be shifted in the -x direction with respect to the second row RW2, and a portion of the third row RW3 may protrude beyond an edge of the second row RW2. In an embodiment, the fourth row RW4 may be shifted in the -x direction with respect to the third row RW3, and a portion of the fourth row RW4 may protrude beyond an edge of the third row RW3. FIG. 8 shows an embodiment in which the second to fourth rows RW2, RW3, and RW4 are shifted by two pixels PX relative to the first to third rows RW1, RW2, and RW3. However, the disclosure is not necessarily limited thereto, and the shift interval may be variously changed.

The display apparatus 1 may include a plurality of signal lines 21. The plurality of signal lines 21 may extend in the first direction (e.g., the +y direction or the -y direction) and may be connected to the plurality of pixels PX. In an embodiment, the plurality of signal lines 21 may include a first signal line 211, a second signal line 212, a third signal line 213, and a fourth signal line 214. The first to fourth signal lines 211, 212, 213, and 214 may each include a plurality of lines, as shown in FIG. 8, or may have a single line. Each of the signal lines may be connected to a corresponding column of pixels PX. In an embodiment, the first signal line 211 may be connected to the first row RW1 of pixels PX. In an embodiment, the second signal line 212 may be connected to the second row RW2 of pixels PX. In an embodiment, the third signal line 213 may be connected to the third row RW3 of pixels PX. In an embodiment, the fourth signal line 214 may be connected to the fourth row RW4 of pixels PX.

The plurality of signal lines 21 may be configured to transmit electrical signals to corresponding rows of pixels PX. In an embodiment, the first signal line 211 may be configured to transmit an electrical signal to the first row RW1 of pixels PX. In an embodiment, the second signal line 212 may be configured to transmit an electrical signal to the second row RW2 of pixels PX. In an embodiment, the third signal line 213 may be configured to transmit an electrical signal to the third row RW3 of pixels PX. In an embodiment, the fourth signal line 214 may be configured to transmit an electrical signal to the fourth row RW4 of pixels PX.

The display apparatus 1 may include a plurality of signal supply lines 20. The plurality of signal supply lines 20 may extend in directions oblique to the first direction (e.g., the +y direction or the -y direction) and the second direction (e.g., the +x direction or the -x direction). The plurality of signal supply lines 20 may be connected to the plurality of signal lines 21. In an embodiment, the plurality of signal supply lines 20 may come into contact with the plurality of signal lines 21, respectively, in an overlapping area with the plurality of signal lines 21. In an embodiment, some the plurality of signal supply lines 20 may be configured to supply the scan signal Sn (see FIG. 6) to at least some of the plurality of signal lines 21, and the signal lines receiving the scan signal Sn (see FIG. 6) may be viewed as the scan lines SL (see FIG. 6). In an embodiment, some of the plurality of signal supply lines 20 may be configured to supply the data signal Dm (see FIG. 6) to at least some of the plurality of signal lines 21, and signal lines receiving the data signal Dm (see FIG. 6) may be viewed as the data lines DL (see FIG. 6). In an embodiment, some of the plurality of signal supply lines 20 may be configured to supply the driving voltage ELVDD (see FIG. 6) to at least some of the plurality of signal lines 21, and the signal lines receiving the driving voltage ELVDD (see FIG. 6) may be viewed as the driving voltage lines PL (see FIG. 6).

In an embodiment, the plurality of signal lines 21 may be disposed in the second conductive layer 105 and/or the third conductive layer 107 (see FIG. 7). In an embodiment, the plurality of signal supply lines 20 may be disposed in the fourth conductive layer 109 (see FIG. 7).

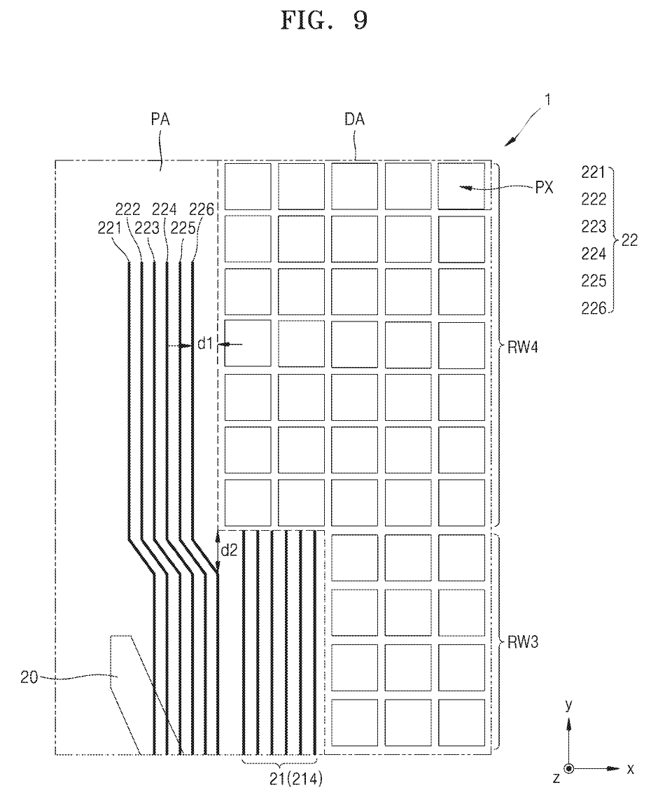

The display apparatus 1 may further include a plurality of dummy lines 22 (see FIGS. 9-12), but the plurality of dummy lines 22 are not shown in FIG. 8. The display apparatus 1 may further include, for example, signal lines arranged in the +x direction of the first signal line 211, but this is not shown in FIG. 8.

Hereinafter, the objective and effects of the disclosure are described in detail with reference to FIG. 8.

In a process of providing electrical signals and/or voltages to the plurality of signal lines 21 through the plurality of signal supply lines 20, static electricity may be introduced into the plurality of signal lines 21 through the plurality of signal supply lines 20. The static electricity may be released around the plurality of signal lines 21 and may flow into the pixels PX of the display area DA. When static electricity is introduced, a failure due to static electricity may occur in at least one pixel PX, for example, in the pixel circuit PC of the pixel PX (see FIG. 6). For example, a failure may occur in the thin-film transistor TFT (see FIG. 7) included in the pixel circuit PC (see FIG. 6), and the failure may cause a failure of the light-emitting diode LED (see FIG. 7), such as a lighting failure. In a case where there are signal lines adjacent to each other, for example, in the case of the first to third signal lines 211, 212, and 213, the static electricity may be divided and disposed between the adjacent signal lines so that the failure due to the static electricity release described above may be reduced. However, in the case of a signal line disposed at the outermost end, for example, the fourth signal line 214, a failure may occur relatively frequently in pixels PX connected to the fourth signal line 214, for example, the pixels PX in the fourth row RW4, due to the absence of adjacent signal lines with which to share the static electricity.

To resolve this, the disclosure provides the plurality of dummy lines 22 (see FIGS. 9-12) arranged adjacent to the outermost signal line, for example, the fourth signal line 214. The arrangement, shape, and dimensions of the plurality of dummy lines 22 are described in detail below with reference to FIGS. 9-12.

FIG. 9 is an enlarged plan view of a display apparatus according to an embodiment.

Referring to FIG. 9, the plurality of dummy lines 22 may be disposed in the peripheral area PA adjacent to the plurality of signal lines 21. In an embodiment, the plurality of dummy lines 22 may be disposed outside of the plurality of signal lines 21. In an embodiment, the plurality of signal lines 21 may be positioned between the plurality of dummy lines 22 and the display area DA. In an embodiment, as shown in FIG. 9, the plurality of dummy lines 22 may be disposed on the -x direction side of the plurality of signal lines 21, for example, the fourth signal line 214. The plurality of dummy lines 22 may be separated from the plurality of pixels PX. For example, the plurality of dummy lines 22 may be lines which are not connected to the plurality of pixels PX.

The plurality of dummy lines 22 extend in the first direction (e.g., the +y direction or the -y direction) as a whole, but the extension path may be bent according to a curvature of the display apparatus 1 and the display area DA. In an embodiment, the plurality of dummy lines 22 may extend in the first direction (e.g., the +y direction or the -y direction), as shown in FIG. 9, may be bent in directions oblique to the first direction (e.g., the +y direction or the -y direction) and the second direction (e.g., the +x direction or the -x direction), and then may be bent again to extend in the first direction (e.g., the +y direction or the -y direction). In an embodiment, at least some, for example, all, of the plurality of dummy lines 22 may extend beyond points where the plurality of signal lines 21 are connected to the plurality of pixels PX. In an embodiment, first to sixth dummy lines 221, 222, 223, 224, 225, and 226 may extend in the +y direction beyond a point where the fourth signal line 214 is connected to the fourth row RW4 of pixels PX. In an embodiment, the plurality of dummy lines 22 may be connected to the signal supply line 20.

In an embodiment, the plurality of dummy lines 22 may include a first dummy line 221, a second dummy line 222, a third dummy line 223, a fourth dummy line 224, a fifth dummy line 225, and a sixth dummy line 226. The first to sixth dummy lines 221, 222, 223, 224, 225, and 226 may be arranged in the second direction (e.g., the +x direction or the -x direction). In an embodiment, the second dummy line 222 may be positioned between the first dummy line 221 and the display area DA, for example, on the +x direction side of the first dummy line 221. In an embodiment, the third dummy line 223 may be positioned between the second dummy line 222 and the display area DA, for example, on the +x direction side of the second dummy line 222. In an embodiment, the fourth dummy line 224 may be positioned between the third dummy line 223 and the display area DA, for example, on the +x direction side of the third dummy line 223. In an embodiment, the fifth dummy line 225 may be positioned between the fourth dummy line 224 and the display area DA, for example, on the +x direction side of the fourth dummy line 224. In an embodiment, the sixth dummy line 226 may be positioned between the fifth dummy line 225 and the display area DA, for example, on the +x direction side of the fifth dummy line 225. However, the disclosure is not necessarily limited to a specific number of dummy lines, and the number of dummy lines included in the plurality of dummy lines 22 may be changed in various ways.

Ends of the plurality of dummy lines 22 may be aligned in the second direction (e.g., the +x direction or the -x direction). In an embodiment, the ends of the first to sixth dummy lines 221, 222, 223, 224, 225, and 226 may be aligned in the second direction (e.g., the +x direction or the -x direction). For example, the ends of the first to sixth dummy lines 221, 222, 223, 224, 225, and 226 may lie on an imaginary straight line drawn along the second direction (e.g., the +x direction or the -x direction). For example, the ends of the first to sixth dummy lines 221, 222, 223, 224, 225, and 226 might not differ in position along the first direction (e.g., the +y direction or the -y direction).

From among the plurality of dummy lines 22, a dummy line closest to the display area DA may be spaced apart from the display area DA in the first direction (e.g., the +y direction or the -y direction) and the second direction (e.g., the +x direction or the -x direction). In an embodiment, the sixth dummy line 226 closest to the display area DA from among the plurality of dummy lines 22 may be spaced apart from the display area DA in the first direction (e.g., the +y direction or the -y direction) and the second direction (e.g., the +x direction or the -x direction). Alternatively, the sixth dummy line 226 closest to the display area DA from among the plurality of dummy lines 22 may be spaced apart from the pixel PX closest to the peripheral area PA in the first direction (e.g., the +y direction or the -y direction) and the second direction (e.g., the +x direction or the -x direction).

In an embodiment, a distance that a dummy line (e.g., the sixth dummy line 226) closest to the display area DA from among the plurality of dummy lines 22 is spaced apart from the display area DA (or from the pixel PX closest to the peripheral area PA) in the second direction (e.g., the +x direction or the -x direction) may be defined as a first distance d1. In an embodiment, a distance that a dummy line (e.g., the sixth dummy line 226) closest to the display area DA from among the plurality of dummy lines 22 is spaced apart from the display area DA (or from the pixel PX closest to the peripheral area PA) in the first direction (e.g., the +y direction or the -y direction) may be defined as a second distance d2. In an embodiment, the second distance d2 may correspond to a first-direction (e.g., the +y direction or the -y direction) spaced distance between the lowermost portion (e.g., an edge on the -y direction side) of the fourth row RW4 protruding beyond an edge of the third row RW3 of pixels PX and the sixth dummy line 226.

In an embodiment, the first distance d1 may be greater than or equal to about 50 micrometers (μm). In an embodiment, the first distance d1 may be greater than or equal to about 60 μm. In an embodiment, the first distance d1 may be greater than or equal to about 90 μm. In an embodiment, the first distance d1 may be greater than or equal to about 100 μm. In an embodiment, the first distance d1 may correspond to a length of one pixel PX in the second direction (e.g., the +x direction or the -x direction). In an embodiment, the first distance d1 may be substantially equal to a length of one pixel PX in the second direction (e.g., the +x direction or the -x direction).

In an embodiment, the second distance d2 may be greater than or equal to about 50 μm. In an embodiment, the second distance d2 may be greater than or equal to about 60 μm. In an embodiment, the second distance d2 may be greater than or equal to about 90 μm. In an embodiment, the second distance d2 may be greater than or equal to about 100 μm. In an embodiment, the second distance d2 may correspond to a length of one pixel PX in the first direction (e.g., the +y direction or the -y direction). In an embodiment, the second distance d2 may be substantially equal to a length of one pixel PX in the first direction (e.g., the +y direction or the -y direction).

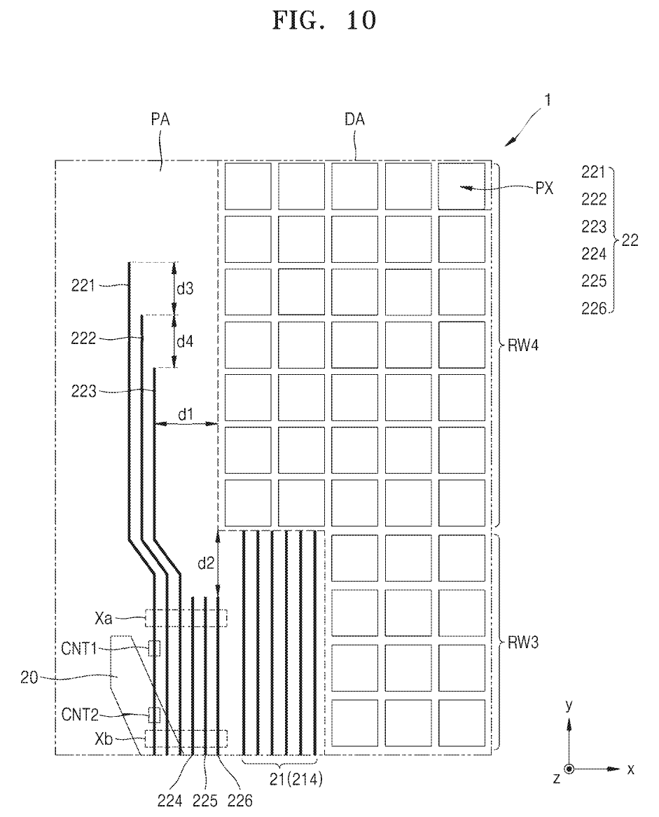

FIG. 10 is an enlarged plan view of a display apparatus according to an embodiment.

Referring to FIG. 10, some of the plurality of dummy lines 22 are arranged such that ends thereof are spaced apart in the first direction (e.g., the +y direction or the -y direction). In an embodiment, the fourth to sixth dummy lines 224, 225, and 226 may be spaced apart from the first to third dummy lines 221, 222, and 223 in the first direction (e.g., the +y direction or the -y direction). In an embodiment, the first dummy line 221, the second dummy line 222, and the third dummy line 223 may be disposed such that ends thereof are spaced apart at a certain interval in the first direction (e.g., the +y direction or the -y direction).

In an embodiment, some of the plurality of dummy lines 22 may further extend in the first direction (e.g., the +y direction or the -y direction) away from the display area DA, such that the ends thereof may be disposed, for example, on the +y direction side. In an embodiment, an end of the first dummy line 221 and an end of the second dummy line 222 may be spaced apart in the first direction (e.g., the +y direction or the -y direction), and the end of the first dummy line 221 may be disposed on the +y direction side of the end of the second dummy line 222. In an embodiment, the end of the second dummy line 222 and an end of the third dummy line 223 may be spaced apart in the first direction (e.g., the +y direction or the -y direction), and the end of the second dummy line 222 may be disposed on the +y direction side of the end of the third dummy line 223.

In an embodiment, the distance in the first direction (e.g., the +y direction or the -y direction) between the end of the first dummy line 221 and the end of the second dummy line 222 may be defined as a third distance d3. In an embodiment, the distance in the first direction (e.g., the +y direction or the -y direction) between the end of the second dummy line 222 and the end of the third dummy line 223 may be defined as a fourth distance d4.

In an embodiment, the third distance d3 and the fourth distance d4 may be greater than or equal to about 50 μm. In an embodiment, the third distance d3 and the fourth distance d4 may be greater than or equal to about 100 μm. In an embodiment, the third distance d3 and the fourth distance d4 may correspond to the length of one pixel PX in the first direction (e.g., the +y direction or the -y direction). In an embodiment, the third distance d3 and the fourth distance d4 may be substantially equal to the length of one pixel PX in the first direction (e.g., the +y direction or the -y direction). In an embodiment, the third distance d3 may be substantially equal to the fourth distance d4.

In the present embodiment, the first distance d1 may correspond to a distance in the second direction (e.g., the +x direction or the -x direction) between a dummy line (e.g., the third dummy line 223) closest to the display area DA in the second direction (e.g., the +x direction or the -x direction) and the display area DA. Alternatively, the first distance d1 may correspond to the distance in the second direction (e.g., the +x direction or the -x direction) between a pixel PX closest to the peripheral area PA and the third dummy line 223.

In an embodiment, the first distance d1 may be greater than or equal to about 50 μm. In an embodiment, the first distance d1 may be greater than or equal to about 60 μm. In an embodiment, the first distance d1 may be greater than or equal to about 90 μm. In an embodiment, the first distance d1 may be greater than or equal to about 100 μm. In an embodiment, the first distance d1 may correspond to the length of one pixel PX in the second direction (e.g., the +x direction or the -x direction). In an embodiment, the first distance d1 may be substantially equal to the length of one pixel PX in the second direction (e.g., the +x direction or the -x direction).

In the present embodiment, some of the plurality of dummy lines 22, for example, the fourth to sixth dummy lines 224, 225, and 226, might not extend to the point where the plurality of signal lines 21 (e.g., the fourth signal line 214) are connected to the plurality of pixels PX (e.g., in the fourth row RW4). For example, the ends of the fourth to sixth dummy lines 224, 225, and 226 may be disposed in the -y direction at the point where the fourth signal line 214 is connected to the fourth row RW4 of pixels PX. Accordingly, the ends of the fourth to sixth dummy lines 224, 225, and 226 may be spaced apart in the first direction (e.g., the +y direction or the -y direction) from the lowermost end (e.g., the edge on the -y direction side) of the fourth row RW4 which protrudes beyond the edge of the display area DA, e.g., the third row RW3. The second distance d2 may correspond to a spaced distance in the first direction (e.g., the +y direction or the -y direction).

In an embodiment, the second distance d2 may be greater than or equal to about 50 μm. In an embodiment, the second distance d2 may be greater than or equal to about 60 μm. In an embodiment, the second distance d2 may be greater than or equal to about 90 μm. In an embodiment, the second distance d2 may be greater than or equal to about 100 μm. In an embodiment, the second distance d2 may correspond to a length of one pixel PX in the first direction (e.g., the +y direction or the -y direction). In an embodiment, the second distance d2 may be substantially equal to the length of one pixel PX in the first direction (e.g., the +y direction or the -y direction).

In an embodiment, when the first distance d1 is greater than the second distance d2, a dummy line disposed closest to the display area DA may be understood as the sixth dummy line 226. In this case, an end of the dummy line (e.g., sixth dummy line 226) disposed closest to the display area DA may be spaced (e.g., the second distance d2) apart from the display area DA in the first direction (e.g., the +y direction or the -y direction). In an embodiment, when the first distance d1 is less than the second distance d2, the dummy line disposed closest to the display area DA may be understood as the third dummy line 223. In this case, an end of the dummy line (e.g., the third dummy line 223) disposed closest to the display area DA may be spaced (e.g., the first distance d1) apart from the display area DA in the second direction (e.g., the +x direction or the -x direction). In either case, the dummy line disposed closest to the display area DA (e.g., the third dummy line 223 or the sixth dummy line 226) may be spaced at least 50 micrometers from the display area DA.

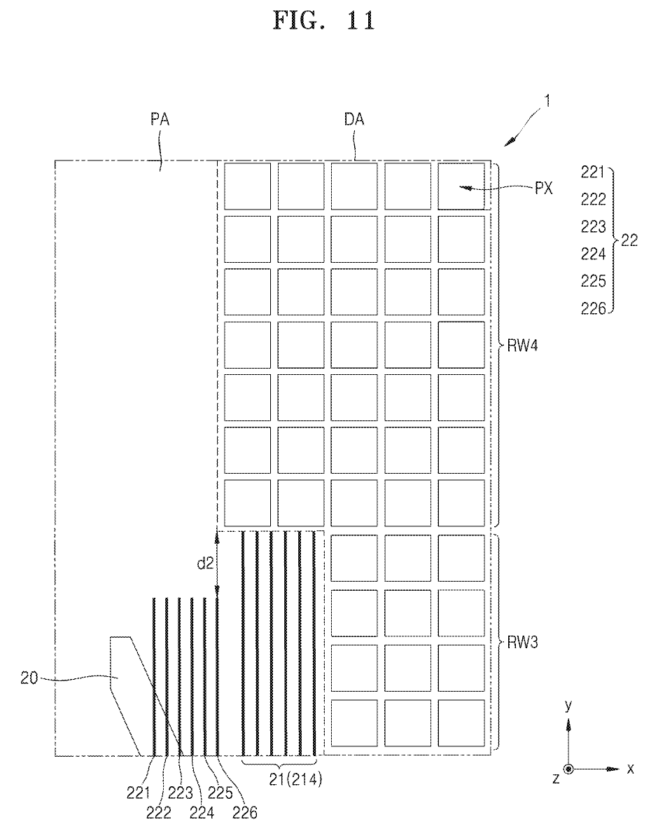

FIG. 11 is an enlarged plan view of a display apparatus according to an embodiment.

Referring to FIG. 11, the plurality of dummy lines 22 might not extend beyond the point where the plurality of signal lines 21 are connected to the plurality of pixels PX. In an embodiment, the first to sixth dummy lines 221, 222, 223, 224, 225, and 226 might not extend beyond the point where the fourth signal line 214 is connected to the fourth row RW4 of pixels PX. Therefore, the ends of the first to sixth dummy lines 221, 222, 223, 224, 225, and 226 may be disposed on the -y direction side of the point where the fourth signal line 214 is connected to the fourth row RW4 of pixels PX. In an embodiment, the ends of the first to sixth dummy lines 221, 222, 223, 224, 225, and 226 may be aligned in the second direction (e.g., the +x direction or the -x direction). For example, the ends of the first to sixth dummy lines 221, 222, 223, 224, 225, and 226 may lie on an imaginary straight line drawn along the second direction (e.g., the +x direction or the -x direction).

The ends of the first to sixth dummy lines 221, 222, 223, 224, 225, and 226 may be spaced apart from the display area DA in the first direction (e.g., the +y direction or the -y direction). In an embodiment, the sixth dummy line 226 may be spaced apart in the first direction (e.g., the +y direction or the -y direction) from the lowermost portion (e.g., the edge on the -y direction side) of the fourth row RW4 which protrudes beyond the edge of the third row RW3. This first-direction (e.g., the +y direction or the -y direction) spaced distance may correspond to the second distance d2. In an embodiment, the plurality of dummy lines 22 do not extend beyond the point where the plurality of signal lines 21 are connected to the plurality of pixels PX, and therefore the first distance d1 (see FIGS. 9 and 10) described above might not be defined.

In an embodiment, the second distance d2 may be greater than or equal to about 50 μm. In an embodiment, the second distance d2 may be greater than or equal to about 60 μm. In an embodiment, the second distance d2 may be greater than or equal to about 90 μm. In an embodiment, the second distance d2 may be greater than or equal to about 100 μm. In an embodiment, the second distance d2 may correspond to the length of one pixel PX in the first direction (e.g., the +y direction or the -y direction). In an embodiment, the second distance d2 may be substantially equal to the length of one pixel PX in the first direction (e.g., the +y direction or the -y direction).

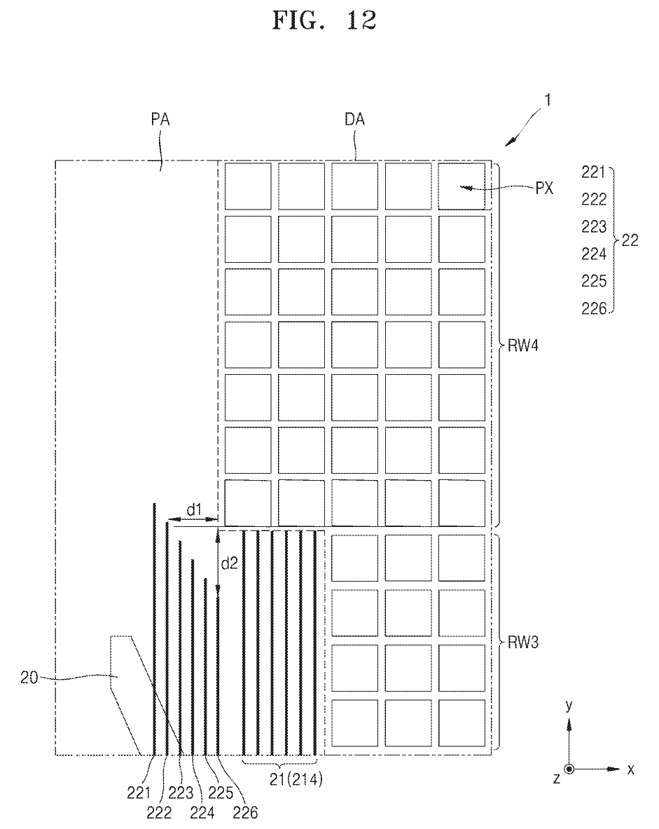

FIG. 12 is an enlarged plan view of a display apparatus according to an embodiment.

Referring to FIG. 12, some of the plurality of dummy lines 22 may extend beyond the point where the plurality of signal lines 21 are connected to the plurality of pixels PX, and the others might not. In an embodiment, the first dummy line 221 and the second dummy line 222 may extend beyond the lowermost portion (e.g., the edge on the -y direction side) of the fourth row RW4, which protrudes beyond the edge of the third row RW3. Accordingly, the ends of the first dummy line 221 and the second dummy line 222 may be disposed on the +y direction side of the point where the fourth signal line 214 is connected to the fourth row RW4 of pixels PX. In an embodiment, the third to sixth dummy lines 223, 224, 225, and 226 might not extend beyond the lowermost portion (e.g., the edge on the -y direction side) of the fourth row RW4, which protrudes beyond the edge of the third row RW3. Accordingly, each of the ends of the third to sixth dummy lines 223, 224, 225, and 226 may be disposed on the -y direction side of the point where the fourth signal line 214 is connected to the fourth row RW4 of pixels PX.

In an embodiment, the ends of the plurality of dummy lines 22 may be spaced apart from each other in the first direction (e.g., the +y direction or the -y direction). In an embodiment, the ends of the first to sixth dummy lines 221, 222, 223, 224, 225, and 226 may be spaced apart from each other in the first direction (e.g., the +y direction or the -y direction). In an embodiment, the ends of the first to sixth dummy lines 221, 222, 223, 224, 225, and 226 may be spaced apart from each other in the first direction (e.g., the +y direction or the -y direction) by the same distance. For example, the ends of the first to sixth dummy lines 221, 222, 223, 224, 225, and 226 may be spaced apart at a constant interval in the first direction (e.g., the +y direction or the -y direction).

In the present embodiment, the first distance d1 may be defined as a distance in the second direction (e.g., the +x direction or the -x direction) between a dummy line (e.g., the second dummy line 222) which overlaps the fourth row RW4 of pixels PX and is closest to the display area DA when viewed along the second direction (e.g., the +x direction or the -x direction) and the display area DA. In the present embodiment, the second distance d2 may be defined as the distance in the first direction (e.g., the +y direction or the -y direction) between a dummy line (e.g., the sixth dummy line 226) which overlaps fourth row RW4 of pixels PX and is closest to the display area DA when viewed along the first direction (e.g., the +y direction or the -y direction) and the display area DA.

In an embodiment, the first distance d1 may be greater than or equal to about 50 micrometers (μm). In an embodiment, the first distance d1 may be greater than or equal to about 60 μm. In an embodiment, the first distance d1 may be greater than or equal to about 90 μm. In an embodiment, the first distance d1 may be greater than or equal to about 100 μm. In an embodiment, the first distance d1 may correspond to a length of one pixel PX in the second direction (e.g., the +x direction or the -x direction). In an embodiment, the first distance d1 may be substantially equal to a length of one pixel PX in the second direction (e.g., the +x direction or the -x direction).

In an embodiment, the second distance d2 may be greater than or equal to about 50 μm. In an embodiment, the second distance d2 may be greater than or equal to about 60 μm. In an embodiment, the second distance d2 may be greater than or equal to about 90 μm. In an embodiment, the second distance d2 may be greater than or equal to about 100 μm. In an embodiment, the second distance d2 may correspond to the length of one pixel PX in the first direction (e.g., the +y direction or the -y direction). In an embodiment, the second distance d2 may be substantially equal to the length of one pixel PX in the first direction (e.g., the +y direction or the -y direction).

By arranging the plurality of dummy lines 22 as described with reference to FIGS. 9-12, the static electricity within the plurality of signal lines 21 may be shared by the plurality of dummy lines 22, and the ends of the plurality of dummy lines 22 may be spaced apart from the display area DA and the plurality of pixels PX by a sufficient distance (e.g., 50 μm or more). Therefore, the static electricity released from the ends of the plurality of dummy lines 22 due to the static electricity shared by the plurality of dummy lines 22 is unlikely to affect the plurality of pixels PX of the display area DA, and failure due to static electricity occurring in the plurality of pixels PX may be prevented (or at least reduced).

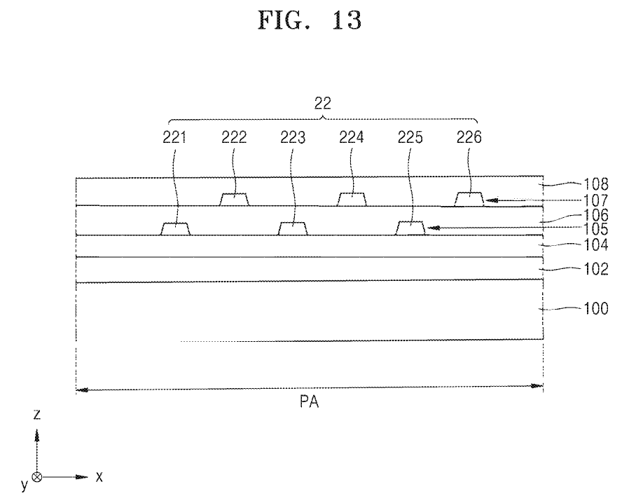

FIG. 13 is a cross-sectional view of a display apparatus according to an embodiment. FIG. 13 may be a cross-sectional view showing the plurality of dummy lines 22 according to an embodiment of one of FIGS. 9-12, for example.

Referring to FIG. 13, the plurality of dummy lines 22 may be disposed in the second conductive layer 105 and the third conductive layer 107. In an embodiment, some of the plurality of dummy lines 22 may be disposed in the second conductive layer 105, and other dummy lines may be disposed in the third conductive layer 107. In an embodiment, dummy lines adjacent to each other from among the plurality of dummy lines 22 may be disposed in different layers. In an embodiment, as shown in FIG. 13, the first, third, and fifth dummy lines 221, 223, and 225 may be disposed in the second conductive layer 105, and the second, fourth, and sixth dummy lines 222, 224, and 226 may be disposed in the third conductive layer 107. In this case, the first, third, and fifth dummy lines 221, 223, and 225 may be disposed in the same layer (e.g., the second conductive layer 105) as the gate electrode GE (see FIG. 7), and the second, fourth, and sixth dummy lines 222, 224, and 226 may be disposed in the same layer (e.g., the third conductive layer 107) as the second capacitor electrode CE2 (see FIG. 7). In an embodiment, the first, third, and fifth dummy lines 221, 223, and 225 may be formed simultaneously with the gate electrode GE (see FIG. 7), and the second, fourth, and sixth dummy lines 222, 224, and 226 may be formed simultaneously with the second capacitor electrode CE2.

In an embodiment, the first, third, and fifth dummy lines 221, 223, and 225 may be disposed in the third conductive layer 107, and the second, fourth, and sixth dummy lines 222, 224, and 226 may be disposed in the second conductive layer 105. In this case, the first, third, and fifth dummy lines 221, 223, and 225 may be disposed in the same layer (e.g., the third conductive layer 107) as the second capacitor electrode CE2 (see FIG. 7), and the second, fourth, and sixth dummy lines 222, 224, and 226 may be disposed in the same layer (e.g., the second conductive layer 105) as the gate electrode GE (see FIG. 7). In an embodiment, the first, third, and fifth dummy lines 221, 223, and 225 may be formed simultaneously with the second capacitor electrode CE2 (see FIG. 7), and the second, fourth, and sixth dummy lines 222, 224, and 226 may be formed simultaneously with the gate electrode GE (see FIG. 7).

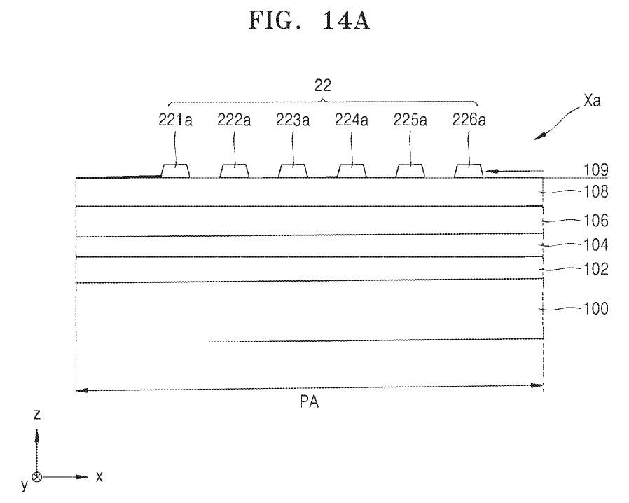

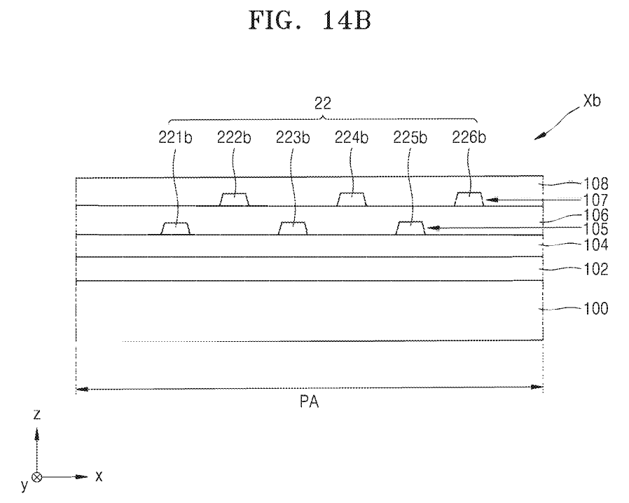

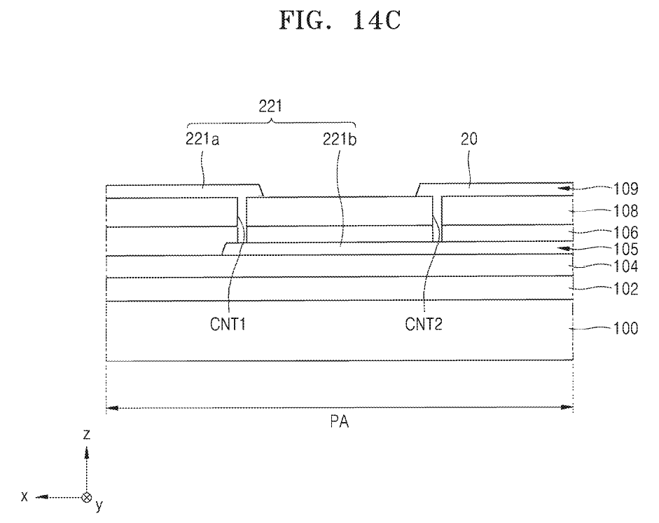

FIGS. 14A, 14B, and 14C are cross-sectional views of a display apparatus according to an embodiment. FIG. 14A may be, for example, a cross-sectional view of a display apparatus in region Xa of FIG. 10. FIG. 14B may be, for example, a cross-sectional view of a display apparatus in region Xb of FIG. 10. FIG. 14C may be, for example, a cross-sectional view across regions Xa and Xb of FIG. 10.

Referring to FIGS. 14A-14C, the plurality of dummy lines 22 may be disposed in different layers, depending on the area. In an embodiment, referring to FIG. 14A, the plurality of dummy lines 22 may include a first-1 dummy line 221a, a second-1 dummy line 222a, a third-1 dummy line 223a, a fourth-1 dummy line 224a, a fifth-1 dummy line 225a, and a sixth-1 dummy line 226a. In an embodiment, referring to FIG. 14B, the plurality of dummy lines 22 may include a first-2 dummy line 221b, a second-2 dummy line 222b, a third-2 dummy line 223b, a fourth-2 dummy line 224b, a fifth-2 dummy line 225b, and a sixth-2 dummy line 226b. The first-1 dummy line 221a and the first-2 dummy line 221b may correspond together to the first dummy line 221 described above. The second-1 dummy line 222a and the second-2 dummy line 222b may correspond together to the second dummy line 222 described above. The third-1 dummy line 223a and the third-2 dummy line 223b may correspond together to the third dummy line 223 described above. The fourth-1 dummy line 224a and the fourth-2 dummy line 224b may correspond together to the fourth dummy line 224 described above. The fifth-1 dummy line 225a and the fifth-2 dummy line 225b may correspond together to the fifth dummy line 225 described above. The sixth-1 dummy line 226a and the sixth-2 dummy line 226b may correspond together to the sixth dummy line 226 described above.

In an embodiment, the first-1 dummy line 221a, the second-1 dummy line 222a, the third-1 dummy line 223a, the fourth-1 dummy line 224a, the fifth-1 dummy line 225a, and the sixth-1 dummy line 226a may be disposed in the fourth conductive layer 109. Accordingly, the first-1 dummy line 221a, the second-1 dummy line 222a, the third-1 dummy line 223a, the fourth-1 dummy line 224a, the fifth-1 dummy line 225a, and the sixth-1 dummy line 226a may be disposed in the same layer as the drain electrode DE and the source electrode SE described above (see FIG. 7). In an embodiment, the first-1 dummy line 221a, the second-1 dummy line 222a, the third-1 dummy line 223a, the fourth-1 dummy line 224a, the fifth-1 dummy line 225a, and the sixth-1 dummy line 226a may be formed simultaneously with the drain electrode DE and the source electrode SE (see FIG. 7).

In an embodiment, the first-2 dummy line 221b, the second-2 dummy line 222b, the third-2 dummy line 223b, the fourth-2 dummy line 224b, the fifth-2 dummy line 225b, and the sixth-2 dummy line 226b may be disposed similarly to the first to sixth dummy lines 221, 222, 223, 224, 225, and 226 described with reference to FIG. 13. In an embodiment, the first-2 dummy line 221b, the third-2 dummy line 223b, and the fifth-2 dummy line 225b may be disposed in the second conductive layer 105 and formed simultaneously with the gate electrode GE (see FIG. 7). In an embodiment, the second-2 dummy line 222b, the fourth-2 dummy line 224b, and the sixth-2 dummy line 226b may be disposed in the third conductive layer 107 and formed simultaneously with the second capacitor electrode CE2 (see FIG. 7).

FIG. 14C shows, as an example, the first dummy line 221 from among the plurality of dummy lines 22, for example, the first-1 dummy line 221a and the first-2 dummy line 221b. However, a structure described below may be equally applied to other dummy lines, for example, the second to sixth dummy lines 222, 223, 224, 225, and 226.

The first-1 dummy line 221a may be disposed in the fourth conductive layer 109, the first-2 dummy line 221b may be disposed in the second conductive layer 105, and the signal supply line 20 may be disposed in the fourth conductive layer 109. The first-1 dummy line 221a and the first-2 dummy line 221b may be (e.g., electrically) connected at a first connection portion CNT1. In an embodiment, the first connection portion CNT1 may be a contact hole formed in the third insulating layer 106 and the fourth insulating layer 108, simultaneously overlapping the first-1 dummy line 221a and the first-2 dummy line 221b. The first-2 dummy line 221b and the signal supply line 20 may be (e.g., electrically) connected at a second connection portion CNT2. In an embodiment, the second connection portion CNT2 may be a contact hole formed in the third insulating layer 106 and the fourth insulating layer 108, simultaneously overlapping the first-2 dummy line 221b and the signal supply line 20.

Although the embodiments of FIGS. 14A-14C are described with reference to the embodiment shown in FIG. 10, the structure described above may also be similarly applied to the embodiment shown in FIGS. 9, 11, or 12.

According to one or more embodiments, a display apparatus is provided which can prevent failure of a pixel due to static electricity from signal lines which provide an electrical signal to the pixel. According to one or more embodiments, an electronic device including a display apparatus having the features described above is provided.

It should be understood that embodiments described herein should be considered in a descriptive sense and not necessarily for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope of the present disclosure.

What is claimed is:

1. A display apparatus, comprising:
a substrate including a display area and a peripheral area;
a plurality of pixels disposed in the display area, each of the plurality of pixels including at least one light-emitting diode and at least one pixel circuit;
a plurality of signal lines electrically connected to the plurality of pixels, each of the plurality of signal lines extending in a first direction; and
a plurality of dummy lines adjacent to the plurality of signal lines and disposed within the peripheral area, spaced apart from the plurality of pixels, and each of the plurality of dummy lines extending in the first direction,
wherein ends of at least some dummy lines from among the plurality of dummy lines are spaced apart from one another in the first direction.

2. The display apparatus of claim 1, wherein the plurality of dummy lines includes a first dummy line and a second dummy line, the second dummy line is disposed between the first dummy line and the display area, and an end of the first dummy line extends farther in the first direction than does an end of the second dummy line.

3. The display apparatus of claim 2, wherein a distance in the first direction between the end of the first dummy line and the end of the second dummy line corresponds to a length of one of the plurality of pixels in the first direction.

4. The display apparatus of claim 1, wherein a dummy line disposed closest to the display area from among the plurality of dummy lines is spaced at least 50 micrometers apart from the display area.

5. The display apparatus of claim 4, wherein an end of the dummy line disposed closest to the display area is spaced apart from the display area in a second direction, which crosses the first direction.

6. The display apparatus of claim 1, wherein ends of some dummy lines from among the plurality of dummy lines are spaced apart from the display area in the first direction.

7. The display apparatus of claim 6, wherein a distance that the ends of the some dummy lines are spaced apart from the display area corresponds to a length of one of the plurality of pixels in the first direction.

8. The display apparatus of claim 1, wherein some dummy lines from among the plurality of dummy lines extend beyond points where the plurality of signal lines are electrically connected to the plurality of pixels in the first direction.

9. The display apparatus of claim 1, wherein the at least one pixel circuit of each of the plurality of pixels includes a thin-film transistor electrically connected to the at least one light-emitting diode, wherein the thin-film transistor includes a semiconductor pattern, a gate electrode disposed on the semiconductor pattern, and a source electrode and a drain electrode disposed on the gate electrode.

10. The display apparatus of claim 9, wherein some dummy lines from among the plurality of dummy lines are disposed in a same layer as the gate electrode.

11. The display apparatus of claim 9, wherein a portion of the plurality of dummy lines is disposed in a same layer as the source electrode and the drain electrode, and another portion of the plurality of dummy lines is disposed in a same layer as the gate electrode.

12. The display apparatus of claim 1, wherein two dummy lines adjacent to each other from among the plurality of dummy lines are disposed in different layers from one another.

13. The display apparatus of claim 1, further comprising a plurality of signal supply lines configured to supply, to the plurality of signal lines, signals for driving the plurality of pixels,
wherein at least some signal supply lines from among the plurality of signal supply lines are electrically connected to the plurality of dummy lines.

14. A display apparatus, comprising:
a substrate including a display area and a peripheral area;
a plurality of pixels disposed in the display area, each of the plurality of pixels including at least one light-emitting diode and at least one pixel circuit;
a plurality of signal lines electrically connected to the plurality of pixels, each of the plurality of signal lines extending in a first direction; and
a plurality of dummy lines adjacent to the plurality of signal lines and disposed within the peripheral area, separated from the plurality of pixels, and each of the plurality of dummy lines extending in the first direction,
wherein a distance between a dummy line disposed closest to the display area from among the plurality of dummy lines and a pixel disposed closest to the peripheral area from among the plurality of pixels is at least 50 micrometers.

15. The display apparatus of claim 14, wherein the distance is a distance measured in the first direction.

16. The display apparatus of claim 14, wherein the distance is a distance measured in a second direction, which crosses the first direction.

17. The display apparatus of claim 14, wherein at least some dummy lines from among the plurality of dummy lines extend beyond points where the plurality of signal lines are electrically connected to the plurality of pixels in the first direction.

18. The display apparatus of claim 14, wherein ends of at least some dummy lines from among the plurality of dummy lines are spaced apart from one another in the first direction.

19. The display apparatus of claim 14, wherein the distance corresponds to a length of a pixel from among the plurality of pixels, the length being measured in the first direction or in a second direction crossing the first direction.

20. An electronic device, comprising a display apparatus and a processor configured to drive the display apparatus, wherein the display apparatus includes:
a substrate including a display area and a peripheral area;
a plurality of pixels disposed in the display area, each of the plurality of pixels including at least one light-emitting diode and at least one pixel circuit;
a plurality of signal lines electrically connected to light-emitting diodes of the plurality of pixels; and
a plurality of dummy lines adjacent to the plurality of signal lines and disposed within the peripheral area, spaced apart from the plurality of pixels,
wherein ends of at least some dummy lines from among the plurality of dummy lines are spaced apart from one another in a first direction in which each of the plurality of dummy lines extend.
